(19) United States
(12) Patent Application Publication
(10) Pub. No.: US 2025/0220855 A1
(43) Pub. Date: Jul. 3, 2025

(54) GAS COOLING MODULE FOR IMMERSION ELECTRONIC APPARATUS AND TEST DEVICE EQUIPPED WITH GAS COOLING MODULE

(71) Applicant: Wiwynn Corporation, New Taipei City (TW)

(72) Inventors: Tsung-Han LI, New Taipei City (TW); Kang-Bin MAH, New Taipei City (TW); Chih-An LIAO, New Taipei City (TW); Ting-Yu PAI, New Taipei City (TW)

(21) Appl. No.: 18/987,080

(22) Filed: Dec. 19, 2024

Related U.S. Application Data
(60) Provisional application No. 63/617,144, filed on Jan. 3, 2024.

(30) Foreign Application Priority Data
Nov. 19, 2024 (TW) 113144521

(51) Int. Cl. H05K 7/20

(52) U.S. Cl. CPC H05K 7/20318; H05K 7/203; H05K 7/20327

(57) ABSTRACT

A gas cooling module for an immersion electronic apparatus and a test device equipped with the gas cooling module are provided. The immersion electronic apparatus includes a boiler disposed on a heat source of a circuit board. The gas cooling module includes a gas supply source and a fluid guide member. Cooling gas is introduced from the gas supply source into the fluid guide member, and is ejected toward the boiler, so that heat can be effectively taken away, and the immersion electronic apparatus can be tested in an air environment. The test device further integrates a housing, the immersion electronic apparatus is placed in the housing, and the test device is equipped with the foregoing gas cooling module, to perform a more comprehensive performance test.

### CROSS-REFERENCE TO RELATED APPLICATIONS

This non-provisional application claims the benefit of U.S. provisional application Ser. No. 63/617,144, filed on Jan. 3, 2024 and claims the priority of patent application Ser. No. 11/314,4521, filed in Taiwan, R.O.C. on Nov. 19, 2024. The entire of the above-mentioned patent applications is hereby incorporated by references herein and made a part of the specification.

### BACKGROUND

### Technical Field

A gas cooling module that can provide gas cooling for a specific electronic apparatus and a test device for the specific electronic apparatus are provided. The specific electronic apparatus requires the use of an immersion cooling system during normal operation.

### Related Art

An existing two-phase immersion cooling system faces numerous challenges in production and test stages. Specifically, in an early stage of product development, electronic devices are typically required to undergo all tests within the liquid cooling tank. However, due to the insufficient stability of the electronic device itself, it is often necessary to frequently move the device in and out of the liquid cooling tank to perform debugging and troubleshooting, which inadvertently prolongs the production testing time.

Moreover, electronic devices that typically use immersion cooling systems cannot be directly powered on and tested in an air environment. This further extends the product development and verification cycle. The primary reason for this limitation is that when the electronic device is transferred from the liquid cooling tank to an air environment, the thermal conductivity of air is significantly lower than that of liquid, leading to a substantial reduction in the device's heat dissipation performance. Without appropriate cooling measures, the device may overheat and become damaged.

Therefore, in the prior art, when it is necessary to test an electronic device in an air environment, the boiler is often replaced with a conventional heat sink to ensure that the device can operate normally under air cooling conditions. However, this replacement process is not only time-consuming and labor-intensive but also further extends the product development cycle. Additionally, frequent disassembly and reassembly operations may damage the components, thereby increasing costs.

### SUMMARY

An embodiment of the instant disclosure provides a gas cooling module for an immersion electronic apparatus. The immersion electronic apparatus may include a circuit board and a boiler, and the boiler is disposed on a heat source of the circuit board. The gas cooling module includes a gas supply source and a fluid guide member, and the fluid guide member is fluidly connected the gas supply source. In response to the gas supply source supplying cooling gas to the fluid guide member, the fluid guide member ejects the cooling gas toward the boiler.

An embodiment of the instant disclosure provides a test device for an immersion electronic apparatus. The immersion electronic apparatus includes a circuit board and a boiler, and the boiler is disposed on a heat source of the circuit board. The test device includes a housing, a gas supply source, and a fluid guide member. The housing at least partially covers the immersion electronic apparatus. The fluid guide member is fluidly connected to the gas supply source, and is fixed on the housing. In response to the gas supply source supplying cooling gas to the fluid guide member, the fluid guide member ejects the cooling gas toward the boiler.

An embodiment of the instant disclosure provides a test device for an immersion electronic apparatus, and the test device includes the immersion electronic apparatus, a housing, a gas supply source, and a fluid guide member. The immersion electronic apparatus includes a circuit board and a boiler, and the boiler is disposed on a heat source of the circuit board. The housing at least partially covers the immersion electronic apparatus. The fluid guide member is fluidly connected to the gas supply source, and is fixed on the housing. In response to the gas supply source supplying cooling gas to the fluid guide member, the fluid guide member ejects the cooling gas toward the boiler.

### BRIEF DESCRIPTION OF THE DRAWINGS

FIG. 1 is a schematic diagram of a test device for an immersion electronic apparatus according to an embodiment of the instant disclosure;

FIG. 2 is a partial cross-sectional view of FIG. 1, showing a circuit board, a boiler, and a fluid guide member;

FIG. 3 is a diagram illustrating the relationship between time, a temperature, and a power of a test device for an immersion electronic apparatus according to an embodiment of the instant disclosure;

FIG. 4 is a schematic diagram of a test device for an immersion electronic apparatus according to an embodiment of the instant disclosure;

FIG. 5 is a schematic diagram of a test device for an immersion electronic apparatus according to an embodiment of the instant disclosure;

FIG. 6 is a schematic diagram of a test device for an immersion electronic apparatus according to an embodiment of the instant disclosure;

FIG. 7A is a perspective view of a test device for an immersion electronic apparatus according to an embodiment of the instant disclosure;

FIG. 7B is a cross-sectional view of a test device for an immersion electronic apparatus according to an embodiment of the instant disclosure; and

FIG. 8 is a perspective view of a housing of a test device for an immersion electronic apparatus according to an embodiment of the instant disclosure.

### DETAILED DESCRIPTION

Various embodiments are provided below for detailed description. However, the embodiments are merely used as examples for description, and do not limit the protection scope of the instant disclosure. In addition, some components are omitted in the drawings in the embodiments, to clearly show technical features of the instant disclosure. Further, same reference numerals in all the drawings are used to indicate same or similar components. The drawings of the instant disclosure are merely for exemplary descriptions and may not be drawn to scale, and not all details are presented in the drawings.

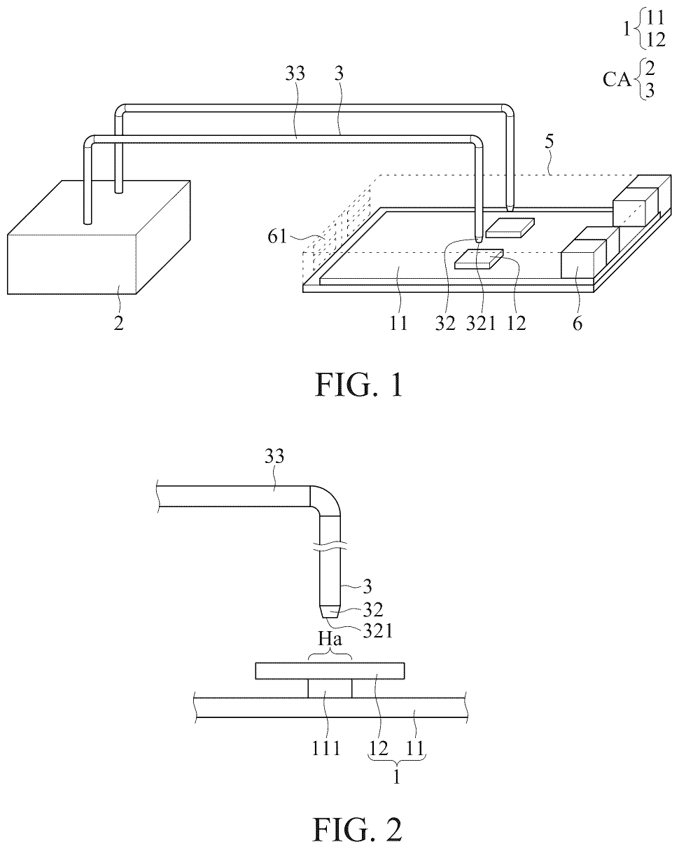

Referring to both FIG. 1 and FIG. 2, FIG. 1 is a schematic diagram of a test device for an immersion electronic apparatus 1 according to an embodiment of the instant disclosure, and FIG. 2 is a partial cross-sectional view of FIG. 1, showing a circuit board 11, a boiler 12, and a fluid guide member 3. In the embodiment shown in FIG. 2, the immersion electronic apparatus 1 includes a circuit board 11 and a boiler 12, and the boiler 12 is disposed on a heat source of the circuit board 11. The heat source is typically a chip 111 or another high-power electronic component, such as a CPU, a GPU, a TPU, an FPGA, an ASIC, an XPU, an NPU, a DPU, an ASIC, or another semiconductor integrated circuit with high thermal design power (TDP).

The boiler 12 is a heat exchange component used in an immersion cooling system. Its primary function is to rapidly transfer the heat generated by the heat source to a coolant. For example, in some immersion cooling systems, when the chip 111 is in operation, heat generated by the chip 111 is conducted to the boiler 12, and the coolant vaporizes on a surface of the boiler 12 and forms bubbles. Similar to bubbles generated when water boils, the bubbles continuously form and collapse, quickly dissipating the heat from both the boiler 12 and the chip 111.

In some embodiments, the boiler 12 may be a porous metal plate, and is directly attached to the chip 111. In other embodiments, the boiler 12 may further include a thermal interface, such as a thermal copper plate or a vapor chamber. The thermal interface can be disposed between the boiler 12 and the chip 111 to provide excellent heat conduction and temperature uniformity.

In the embodiment shown in FIG. 1, the test device for the immersion electronic apparatus 1 mainly includes a housing 5 and a gas cooling module CA, and the gas cooling module CA may include a gas supply source 2 and the fluid guide member 3. The housing 5 at least partially covers the immersion electronic apparatus 1. In some embodiments, the housing 5 may be a cover and is directly placed on the circuit board 11.

In addition, the gas supply source 2 may be a centralized air pressure source within the facility, a high-pressure gas cylinder, or an air compressor. In addition, gas provided by the gas supply source 2 may be air, or may be other gas such as inert gas or low-temperature gas. The temperature of the supplied gas can be selected as desired, preferably at or below room temperature. In some embodiments, the gas supply source 2 may also be equipped with a cooling device to lower the gas temperature. The cooling device may include, but is not limited to, a gas cooling system composed of a compressor, condenser, and evaporator, an evaporative cooler, a heat exchanger with a cooling loop, an adsorption chiller, or a thermoelectric cooler (TEC) heat exchanger.

In addition, the fluid guide member 3 is fluidly connected to the gas supply source 2, and is fixed on the housing 5. In some embodiments, the fluid guide member 3 may include a gas pipeline 33 and a nozzle 32. One end of the gas pipeline 33 is connected to the gas supply source 2, while the other end is equipped with the nozzle 32. The opening 321 of the nozzle 32 is directed toward the boiler 12. In addition to accelerating the flow of fluid, the nozzle 32 may also simultaneously cool the fluid passing there through, such as by using a de Laval nozzle, a convergent-divergent nozzle, a coaxial nozzle, a variable geometry nozzle, or a multiphase flow nozzle.

In addition, in the embodiment shown in FIG. 1, a vent unit 6 is disposed on a side of the housing 5, which is suitable for ventilating an interior of the housing 5, to further improve heat dissipation efficiency. In some embodiments, the vent unit 6 may be an exhaust fan, which is disposed on a side wall of the housing 5, and an air vent 61 may be provided on another side wall of the housing 5 corresponding to the vent unit 6. When the vent unit 6 is in operation, external air may enter the housing 5 through the air vent 61, and high-temperature air in the housing 5 is simultaneously discharged by the vent unit 6, thereby effectively reducing a temperature inside the housing 5.

Still referring to FIG. 1 and FIG. 2, when the gas supply source 2 supplies cooling gas to the fluid guide member 3, the cooling gas flows through the gas pipeline 33, and is ejected toward the boiler 12 through the nozzle 32, to cool the boiler 12 and the chip 111. In addition, in some embodiments, to improve heat dissipation efficiency of the boiler 12, a surface area of the boiler 12 is typically increased, and the boiler 12 can completely cover the chip 111.

In some embodiments, when the gas supply source 2 supplies the cooling gas to the fluid guide member 3, the nozzle 32 ejects the cooling gas toward a heating area Ha on the boiler 12, where the heating area Ha corresponds to an upper surface of the chip 111. Further, the heating area Ha has a shorter heat conduction path and lower thermal resistance, making it typically the region of the boiler 12 with a higher temperature. Therefore, by directly ejecting the cooling gas onto the heat generation area Ha corresponding to the chip 111, improved heat dissipation performance can be achieved.

However, the instant disclosure is not limited thereto. In other embodiments, when a large-area chip 111 needs to be cooled, and the cooling gas flow cannot fully cover the entire chip 111, only hotspots on the chip 111 with higher thermal design power (TDP) may be targeted for cooling. The hot spot is a high-heat area on the chip 111. In other words, in some embodiments, the nozzle 32 of the fluid guide member 3 may be aligned with a specific heating area Ha on the boiler 12 corresponding to the hot spot, and jet cooling may be performed on the specific heating area Ha, to obtain better heat dissipation efficiency. Additionally, in other embodiments, such as when a plurality of chips 111 share one boiler 12, or when a large chip 111 has a plurality of hotspots, a plurality of fluid guide members 3 can be configured to jet-cool a plurality of heating areas Ha on the boiler 12 simultaneously.

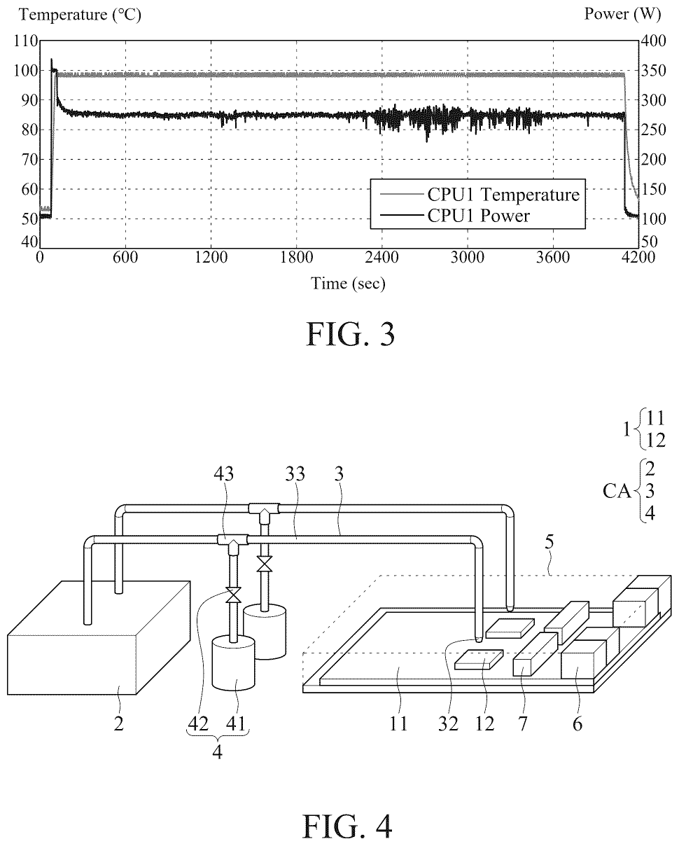

Referring to FIG. 1 to FIG. 3, FIG. 3 is a diagram illustrating the relationship between time, a temperature, and a power of a test device for an immersion electronic apparatus 1 according to an embodiment of the instant disclosure. Experimental results show that, in an experiment using a server main board as an example, when the chip 111 (CPU) continuously operates for more than one hour at a high power of approximately 275 W on average, the gas cooling module CA is capable of maintaining the temperature of the chip 111 below 100° C. In addition, in this experiment, air is used as cooling gas. A flow rate of the gas supplied by the gas supply source 2 ranges from about 15 CFM to 30 CFM, the temperature of the gas ranges from about 20° C. to 25° C., and a cross-sectional area of an outlet of the nozzle 32 is about 50 mm².

From the above, it can be seen that certain embodiments of the instant disclosure, effective heat dissipation can be performed on the immersion electronic apparatus 1. This is achieved without the need to use an immersion cooling system or to modify the immersion electronic apparatus 1 (for example, replacing the boiler 12 with a heat sink), thereby enabling direct product testing of the immersion electronic apparatus 1 in an air environment.

FIG. 4 is a schematic diagram of a test device for an immersion electronic apparatus 1 according to an embodiment of the instant disclosure. In some embodiments, the gas cooling module CA may further include a phase change medium supply unit 4, which is fluidly connected to the fluid guide member 3. The phase change medium supply unit 4 is configured to supply a phase change medium to the fluid guide member 3, allowing the cooling gas to be mixed with the phase change medium. In some embodiments, the phase change medium supply unit 4 may include a fluid container 41 and a regulating valve 42. The fluid container 41 is used to store the phase change medium and is fluidly connected to the fluid guide member 3. The regulating valve 42 is disposed between the fluid container 41 and the fluid guide member 3.

Further, in some embodiments, the fluid container 41 may be in communication with the gas pipeline 33 through a three-way joint 43, and the regulating valve 42 may be disposed between the fluid container 41 and the gas pipeline 33. The regulating valve 42 may be a solenoid valve, which is capable of opening or closing the supply of the phase change medium. In other embodiments, the regulating valve 42 may be an electrically controlled proportional valve, which allows for more precise control of the flow rate of the phase change medium supplied to the fluid guide member 3. This configuration provides enhanced flexibility in controlling the amount of phase change medium introduced into the cooling gas, thereby optimizing the cooling efficiency of the system.

In some embodiments, the phase change medium may be a low-boiling-point liquid, for example, but not limited to, electronic engineering fluid. The boiling point of the phase change medium may range from 0° C. to 90° C., and a volatilization rate of the phase change medium may be above 10 ml/min. In other embodiments, the phase change medium may alternatively be liquid nitrogen or other liquid with properties such as a low boiling point, low specific heat capacity, weak intermolecular forces, and high volatility. Examples of such liquids include ethanol, isopropyl alcohol, acetone, and liquid ammonia. These phase change media enable rapid evaporation and effective cooling, thereby enhancing the thermal management of the immersion electronic apparatus 1.

When the phase change medium evaporates from the fluid container 41, the vaporized phase change medium mixes with the gas supplied by the gas supply source 2 (e.g., air) to form a cooling gas. During this process, as the liquid phase change medium transitions into a gaseous state, it absorbs heat from the surrounding gas due to the latent heat of vaporization, thereby reducing the temperature of the cooling gas. Furthermore, as the cooling gas flows through the nozzle 32 of the fluid flow guide 3, it undergoes further acceleration and cooling. When the cooling gas is ejected toward the boiler 12 via the nozzle 32, the phase change medium absorbs a large amount of heat from the boiler 12, thereby enhancing the cooling performance.

In addition, in the embodiment shown in FIG. 4, a condensation recovery unit 7 is disposed on one side of the vent unit 6. The condensation recovery unit 7 is configured to condense the phase change medium into a liquid state and recover the phase change medium. This not only can reduce operational costs, but also minimizing the potential hazards posed by the phase change medium to the environment or human health. In some embodiments, the condensation recovery unit 7 may include a low-temperature loop, such as a heat exchanger or a pipeline through which a refrigerant circulates. When the gaseous phase change medium flows through the low-temperature loop of the vent unit 6, it condenses into a liquid state, facilitating its collection and reuse. The condensation recovery unit 7 may be disposed on a side of the vent unit 6, which is not limited to an air inlet side or an air outlet side of the vent unit 6, nor limited to an inner side or an outer side of the housing 5. In other embodiments, the condensation recovery unit 7 may alternatively be disposed on a side of the boiler 12. In some embodiments, the condensation recovery unit 7 is disposed on a downstream side to which the cooling gas flows, ensuring the efficient recovery of the condensed phase change medium.

Experimental results using a cooling gas mixture composed of a phase change medium and air show that, compared to using ambient air alone as the cooling gas, the surface temperature of the boiler 12 can be further reduced by approximately 15° C. to 18° C. The relevant experimental parameters are as follows: The gas supplied by the gas supply source 2 is air, with a flow rate ranging from approximately 15 CFM to 30 CFM and a temperature between approximately 20° C. and 25° C.; the cross-sectional area of the outlet of the nozzle 32 is about 50 mm²; and the phase change medium used is 3M™ Novec™ electronic engineering fluid, which has a volatilization rate of approximately 20 ml/min. These findings demonstrate that, in embodiments where the cooling gas is a mixture of a phase change medium and air, the heat dissipation performance for the immersion electronic apparatus 1 is significantly enhanced.

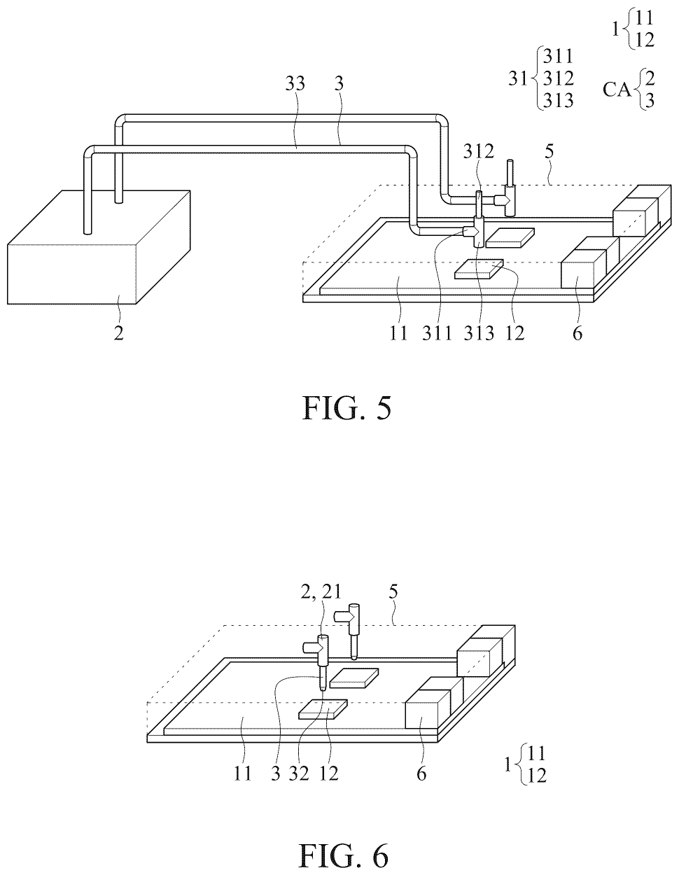

FIG. 5 is a schematic diagram of a test device for an immersion electronic apparatus 1 according to an embodiment of the instant disclosure. In the embodiment shown in FIG. 5, the fluid guide member 3 may further include a vortex tube 31, which may be disposed at a tail end of the gas pipeline 33. The vortex tube 31 includes a fluid inlet 311, a high-temperature gas outlet 312, and a low-temperature gas outlet 313. The fluid inlet 311 is fluidly connected to the gas supply source 2 through the gas pipeline 33, and the low-temperature gas outlet 313 is oriented toward the boiler 12. Therefore, low-temperature gas discharged from the low-temperature gas outlet 313 of the vortex tube 31 can effectively dissipate heat of the immersion electronic apparatus 1. Through this configuration, the cold gas discharged from the low-temperature gas outlet 313 of the vortex tube 31 can effectively cool the immersion electronic apparatus 1, thereby enhancing heat dissipation efficiency.

Further explanation of the operating principle of the vortex tube 31 is as follows: The vortex tube 31 operates based on the vortex effect. When compressed air supplied by the gas supply source 2 enters the fluid inlet 311 of the vortex tube 31, the compressed air undergoes rapid rotational motion. Due to the principle of conservation of angular momentum, the air stream is divided into two distinct parts. One portion of the air rotates along the outer perimeter of the vortex tube 31 and moves toward the high-temperature gas outlet 312, where it becomes heated. The other part of the air moves in an opposite direction along a center and becomes cold, and is finally ejected from the low-temperature gas outlet 313. The other portion of the air moves in the opposite direction along the center of the vortex tube 31, where it experiences a cooling effect and is ultimately discharged from the low-temperature gas outlet 313.

In some embodiments, when the gas supply source 2 supplies compressed air ranging from 6 bar to 8 bar to the vortex tube 31, a cold air jet at a temperature of −40° C. to 10° C. may be generated at the low-temperature gas outlet 313. It should be noted that the vortex tube 31 has no moving parts, which enhances its reliability. The vortex tube 31 requires little to no maintenance, does not use refrigerants, is compact, and low-cost. It does not consume consumables or require electrical power, and it presents no risk of sparks or explosions. By simply supplying compressed air to the fluid inlet 311 of the vortex tube 31, the cold air jet can be immediately generated from the low-temperature gas outlet 313.

FIG. 6 is a schematic diagram of a test device for an immersion electronic apparatus 1 according to an embodiment of the instant disclosure. In the embodiment shown in FIG. 6, the gas supply source 2 may be an airflow generation device 21, including but not limited to an air compressor, a blower, a high-speed fan, or another apparatus that can generate an airflow. In some embodiments, the airflow generation device 21 may be a high-speed fan gun, and may be directly disposed on the housing 5. An airflow outlet of the airflow generation device 21 may be attached to the fluid guide member 3, which then directs the cooling gas towards the boiler 12. Similarly, in this embodiment, a nozzle 32 may also be disposed at an end of the fluid guide member 3 facing the boiler 12, to increase a flow speed of the gas and reduce the temperature of the gas.

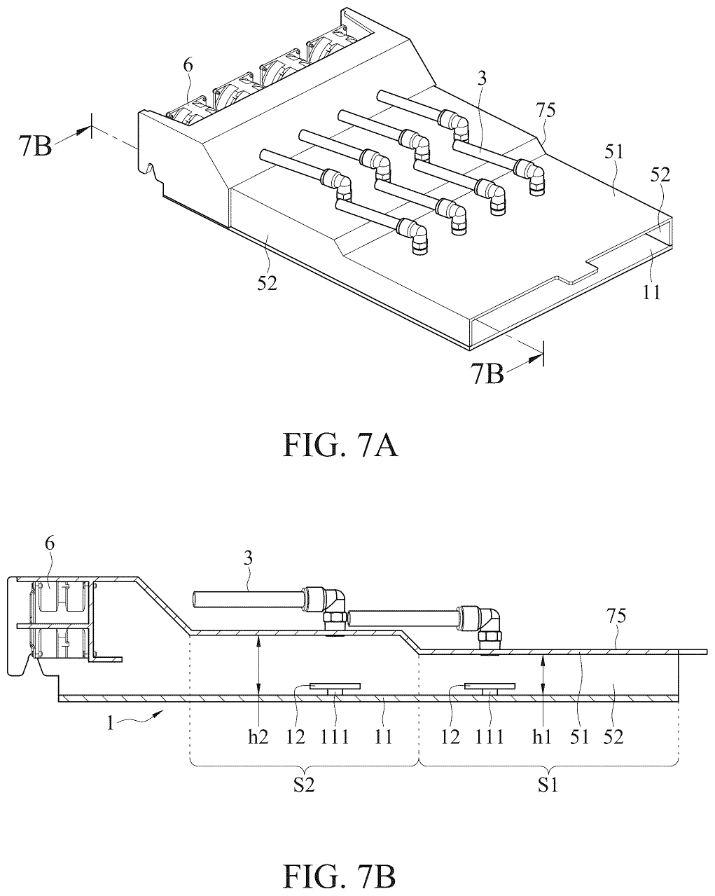

Referring to both FIG. 7A and FIG. 7B, FIG. 7A is a perspective view of a test device for an immersion electronic apparatus 1 according to an embodiment of the instant disclosure, and FIG. 7B is a cross-sectional view of a test device for an immersion electronic apparatus 1 according to an embodiment of the instant disclosure. In the embodiments shown in FIG. 7A and FIG. 7B, a housing 75 includes one main surface 51 and two side end surfaces 52, and the two side end surfaces 52 are respectively connected to two opposite sides of the main surface 51. In some embodiments, the main surface 51 may be shaped in a step-like configuration, thereby forming a plurality of gas chambers of different sizes. The housing 75 and the circuit board 11 of the immersion electronic apparatus 1 jointly define a first gas chamber S1 and a second gas chamber S2, the second gas chamber S2 is larger than the first gas chamber S1, and the vent unit 6 is disposed adjacent to the second gas chamber S2.

Further, in some embodiments, the vent unit 6 may use an exhaust fan, and can be configured on the downstream side of discharged gas. The discharged gas refers to cooling air that has flowed through the boiler 12. Regarding the size of the gas chambers, the gas chambers should gradually increase in size from the upstream side to the downstream side. In other words, the gas chamber near to the vent unit 6 should be larger, to accommodate gas discharged from the upstream side, thereby preventing thermal crosstalk. To achieve this variation in gas chamber size, in some embodiments, the height h2 of the second gas chamber S2 may be greater than the height h1 of the first gas chamber S1. Therefore, the second gas chamber S2 has a larger volume than the first gas chamber S1.

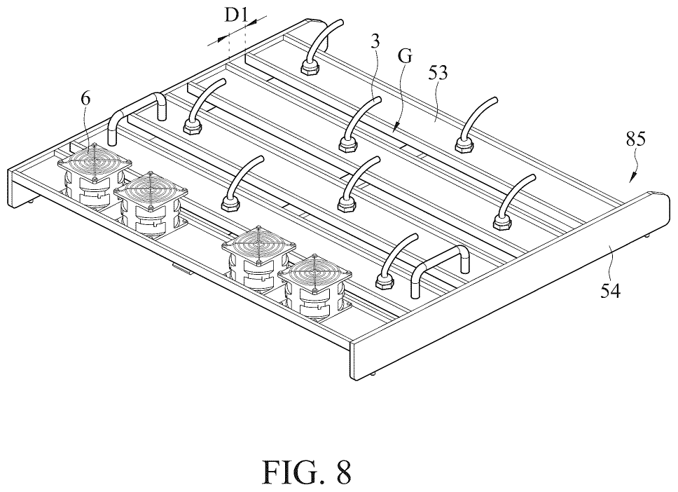

FIG. 8 is a perspective view of a housing 85 of a test device for an immersion electronic apparatus 1 according to an embodiment of the instant disclosure. In the embodiment shown in FIG. 8, another type of housing 85 is used, and the housing 85 includes a plurality of top plates 53 and a mounting frame 54. The top plates 53 are disposed on the mounting frame 54 and are spaced apart from each other at a predetermined distance D1, and the fluid guide members 3 is fixed on the top plates 53.

Further, the top plates 53 are equidistantly arranged on the mounting frame 54, the top plate 53 at an end of the mounting frame 54 is configured to secure the vent unit 6, while the other top plates 53 are configured to secure the fluid guide member 3. Further, the top plates 53 are spaced apart from each other at a predetermined distance D1, leaving the gaps G for the discharge of hot air. In addition, the vent unit 6 may be a gas exhaust apparatus or a blowing apparatus. When the vent unit 6 is the gas exhaust apparatus, the vent unit 6 may extract hot gas between the top plates 53 and the circuit board 11 (referring to FIG. 1 to FIG. 6) of the immersion electronic apparatus 1. When the vent unit 6 is the blowing apparatus, the vent unit 6 may blow external room-temperature gas into a space between the top plates 53 and the circuit board 11 (referring to FIG. 1 to FIG. 6) of the immersion electronic apparatus 1, to forcibly discharge the hot gas from the gaps G between the top plates 53.

Specifically, in some embodiments of the instant disclosure, a gas cooling module CA dedicated to a two-phase immersion cooling system and a test device are provided, to resolve test challenges encountered during the production phase of existing two-phase immersion cooling system. These improvements enhance production efficiency and shorten a product development cycle and a product verification cycle. In some embodiments of the instant disclosure, a test device that can effectively operate in an air environment is designed, so that the immersion electronic apparatus 1 no longer needs to be frequently enter and exit the liquid cooling tank for testing, thereby reducing duration for debugging and troubleshooting. In addition, a problem of insufficient heat dissipation caused by a low thermal conductivity of air can be avoided, normal operation of the immersion electronic apparatus 1 in an atmospheric environment can be ensured. Furthermore, a process of disassembling the boiler 12 and a heat sink is eliminated, thereby reducing a risk of component damage and decreased system sealing. These improvements not only increase the efficiency of production testing but also reduce the difficulty of troubleshooting, shortening the product development cycle and thus improving overall production performance.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A gas cooling module for an immersion electronic apparatus, the immersion electronic apparatus comprising a circuit board and a boiler, wherein the boiler is disposed on a heat source of the circuit board; and the gas cooling module comprising:
a gas supply source; and
a fluid guide member, fluidly connected to the gas supply source;
wherein in response to the gas supply source supplying cooling gas to the fluid guide member, the fluid guide member ejects the cooling gas toward the boiler.

2. The gas cooling module according to claim 1, further comprising a phase change medium supply unit, fluidly connected to the fluid guide member; wherein the phase change medium supply unit is configured to supply a phase change medium to the fluid guide member, the cooling gas is mixed with the phase change medium.

3. The gas cooling module according to claim 2, wherein the phase change medium supply unit comprises a fluid container and a regulating valve, the fluid container is configured to accommodate the phase change medium, and is fluidly connected to the fluid guide member;
the regulating valve is disposed between the fluid container and the fluid guide member.

4. The gas cooling module according to claim 2, wherein the phase change medium is electronic engineering fluid; a boiling point of the phase change medium ranges from 0° C. to 90° C., and a volatilization rate of the phase change medium is above 10 ml/min.

5. The gas cooling module according to claim 1, wherein the fluid guide member comprises a vortex tube; the vortex tube comprises a fluid inlet, a high-temperature gas outlet, and a low-temperature gas outlet; the fluid inlet is fluidly connected to the gas supply source, the low-temperature gas outlet is directed toward the boiler.

6. The gas cooling module according to claim 1, wherein the gas supply source comprises an airflow generation device.

7. The gas cooling module according to claim 1, wherein the fluid guide member comprises a nozzle; an opening of the nozzle is directed toward the boiler.

8. The gas cooling module according to claim 7, wherein the heat source of the circuit board comprises a chip; in response to the gas supply source supplying the cooling gas to the fluid guide member, the nozzle ejects the cooling gas toward a heating area on the boiler; the heating area corresponds to an upper surface of the chip.

9. A test device for an immersion electronic apparatus, the immersion electronic apparatus comprising a circuit board and a boiler, wherein the boiler is disposed on a heat source of the circuit board; and the test device comprising:
a housing, at least partially covering the immersion electronic apparatus;
a gas supply source; and
a fluid guide member, fluidly connected to the gas supply source, and fixed on the housing;
wherein in response to the gas supply source supplying cooling gas to the fluid guide member, the fluid guide member ejects the cooling gas toward the boiler.

10. The test device according to claim 9, further comprising a vent unit, disposed on the housing, and configured to ventilate an interior of the housing.

11. The test device according to claim 10, wherein the housing comprises a main surface and two side end surfaces; the two side end surfaces are respectively connected to two opposite sides of the main surface; the main surface is shaped in a step-like configuration, the housing and the circuit board of the immersion electronic apparatus define a first gas chamber and a second gas chamber, the second gas chamber is larger than the first gas chamber, and the vent unit is disposed adjacent to the second gas chamber.

12. The test device according to claim 11, wherein a height of the second gas chamber is greater than a height of the first gas chamber.

13. The test device according to claim 9, further comprising a phase change medium supply unit, fluidly connected to the fluid guide member; wherein the phase change medium supply unit is configured to supply a phase change medium to the fluid guide member; the cooling gas is mixed with the phase change medium.

14. The test device according to claim 13, further comprising a vent unit and a condensation recovery unit; wherein the vent unit is disposed on the housing, and is configured to ventilate an interior of the housing; the condensation recovery unit is disposed on the housing and adjacent to the vent unit, and the condensation recovery unit is configured to condense the phase change medium into a liquid state.

15. The test device according to claim 9, wherein the housing comprises a plurality of top plates and a mounting frame, the top plates are disposed on the mounting frame and are spaced apart from each other at a predetermined distance, and the fluid guide member is fixed on one of the top plates.

16. The test device according to claim 9, wherein the fluid guide member comprises a vortex tube, and the vortex tube comprises a fluid inlet, a high-temperature gas outlet, and a low-temperature gas outlet; the fluid inlet is fluidly connected to the gas supply source, and the low-temperature gas outlet is directed toward the boiler.

17. The test device according to claim 9, wherein the gas supply source comprises an airflow generation device configured to supply the cooling gas to the fluid guide member.

18. The test device according to claim 9, wherein the fluid guide member comprises a nozzle; the heat source of the circuit board comprises a chip; in response to the gas supply source supplying the cooling gas to the fluid guide member, the nozzle ejects the cooling gas toward a heating area on the boiler; the heating area corresponds to an upper surface of the chip.

19. A test device for an immersion electronic apparatus, comprising:
the immersion electronic apparatus, comprising a circuit board and a boiler, wherein the boiler is disposed on a heat source of the circuit board;
a housing, at least partially covering the immersion electronic apparatus;
a gas supply source; and
a fluid guide member, fluidly connected to the gas supply source, and fixed on the housing;
wherein in response to the gas supply source supplying cooling gas to the fluid guide member, the fluid guide member ejects the cooling gas toward the boiler.

20. The test device according to claim 19, further comprising a phase change medium supply unit, fluidly connected to the fluid guide member; wherein the phase change medium supply unit is configured to supply a phase change medium to the fluid guide member, the cooling gas is mixed with the phase change medium.
